(19) United States
(12) Patent Application Publication
(10) Pub. No.: US 2006/0116835 A1
(43) Pub. Date: Jun. 1, 2006

(54) Measurement of batch properties

(75) Inventors: Rune Mathisen, Skien (NO); Terje V. Karstang, Langesund (NO)

Correspondence Address: OHLANDT, GREELEY, RUGGIERO & PERLE, LLP, ONE LANDMARK SQUARE, 10TH FLOOR, STAMFORD, CT, 06901, US

(73) Assignee: BOREALIS TECHNOLOGY OY

(21) Appl. No.: 10/524,344

(22) PCT Filed: Aug. 12, 2002
(86) PCT No.: PCT/EP02/09021

§ 371 Date: Sep. 1, 2005

(51) Int. Cl. G01R 29/00; G06F 19/00

(52) U.S. Cl. 702/80

(57) ABSTRACT

A bulk property of a product such as pelletized polymer is monitored during production and used as a control input. The polymer is produced in a conventional plant. Polymer fluff from the plant flow, along a conduit to an extrude where it is pelletized. The pellets are fed via a conduit to a silo. The plant is controlled by a computerized control system. As polymer passes along the conduit, a weight loss feeder measures its mass flow rate. It is then passed through a NIR spectrometer. The mass flow rate and the NIR data are transmitted to a data processor where they are used to calculate firstly the instantaneous polymer density and then the bulk density of the polymer in the silo. The output from the data processor is fed to a process controller which, if necessary, makes suitable adjustments to process conditions.

The present invention relates to the measurement of bulk properties of products produced in batches. It is particularly, but not exclusively applicable to products formed as fluids or particles. One useful application of the invention concerns the batch production of polymers.

Polymer production plants produce large quantities of polymer, commonly by means of the continuous Borstar or Phillips processes using loop or gas phase reactors. The raw materials such as monomer, comonomer, catalyst, diluent etc. are supplied to the loop reactor where they are circulated in the form of a slurry. The reactor is maintained under high pressure so that the monomer gas is maintained in liquid form.

In some processes the polymer forms as solid particles of polymer fluff. These are allowed to precipitate out of the slurry in so-called settling legs from which the concentrated slurry is periodically discharged. The solid matter is separated from the diluent in flash tanks where the diluent is allowed to vaporise before being recycled.

The solid is then transported from the reactor entrained in gas in a pneumatic system. In order to produce a product that is in a convenient form for transport to customers, and in order to stabilize the product, the polymer fluff is fed to an extruder in which it is melted, mixed with additives, homogenized and formed into pellets. The pellets are then fed to large silos containing about 70 to 500 tonnes or more of product. Each silo of product comprises a single batch.

It will be appreciated that the control of such a process is highly complex; sophisticated computer-based systems are often used to do this. There are a great number of factors that have an effect on properties of the finished product. For example, the reactor conditions and catalyst properties determine the size of polymer molecules (i.e. the molecular weight), the molecular weight distribution (MWD) and the co-monomer incorporation, that in turn determine the melt flow rate and density of the polymer.

Within each basic type of polymer such as polyethylene, polypropylene etc, products are classified by manufacturers into defined grades. These each have a set of specified properties that must be met within given tolerances. Thus, a grade of polyethylene may be specified as having a certain MFR and a given density.

It follows that in order to produce a given grade of polymer the critical product properties must remain substantially consistent. However, it is inevitable that during a production campaign there will be some significant variation in the instantaneous value of the various parameters concerned. This is not, in itself, a serious problem because these properties will, to some extent, average out within the large volume that forms a batch of production. A small degree of product variation can therefore be tolerated provided that it does not put the bulk property of the batch out of specification.

The conventional way of checking the bulk properties of a batch of polymer is to “blend” the batch (i.e. to mix it thoroughly) and then to take one or more small samples. These are taken to be representative of the bulk properties of the polymer. The samples are then taken away for laboratory analysis in order to check whether they (and therefore also the batch of polymer) are within the specification for the particular grade.

It will be appreciated that this method is very time-consuming and in many cases is too slow to allow any remedial action to be made to the production process. Consequently, it may be discovered too late that the production is not usable as the desired grade. There are also problems with the reliability of any such sampling technique as it relates to what is inevitably a tiny proportion of a, for example, 150 tonne batch.

More recently, useful online measurement techniques have become available. These enable product properties to be measured or determined in almost real time. Thus, on the basis of such measurements, it is possible to monitor the polymer product as is produced. If the product is found to be out of specification, remedial action can be taken by modifying process conditions to bring future production back onto specification.

It will be appreciated that this provides a significant advantage over the earlier technique. However, the inventors have recognized that such a system has a significant drawback: whilst it can prevent further out of specification product from being made, it does not give sufficient information about the effect of the product already made on the bulk properties of the finished product that is already in the silo. The grade of the finished product must still be checked by sampling, as before. Furthermore, it is not possible to remedy the effect of the out of specification production. There are therefore previously unrecognized and significant problems with prior art quality-control techniques.

Viewed from one aspect the present invention provides a method of monitoring a bulk property of a product during its production comprising the steps of of:
a) making repeated on-line measurements of samples of the product to obtain data related to a product property; and
b) using this data, determining a bulk property of the product so far produced.

As mentioned above, and as will be discussed more fully below, the invention is applicable to the production of a wide range of materials, especially those formed as fluids or particles. The field of polymer production is one example, but there are many others such as gas production, drinks, powders, etc.

The bulk property may directly correspond to the product property of step (a). For example, if sample density is measured in step (a) then the bulk property could be the overall density of the batch of product. It may, however, be a property that is derived from the data obtained in step (a) but which is never obtained in respect of the individual samples. An example of this would be a measure of distribution or spread such as the standard deviation of the molecular weight.

Thus, by means of the invention, it is possible to check the grade of a batch of product immediately the batch is complete. There is no need to blend the product and then to take small samples for laboratory analysis. This saves a significant amount of time, and therefore reduces costs compared to the prior art sampling technique. Furthermore, the bulk property data obtained according to the invention is likely to be much more accurate and representative of the product as a whole than the small samples used in the prior art technique.

It is not necessary to wait until the end of production to determine the bulk property; the invention may be used to provide such information about the product produced so far at any stage of production. Indeed, it is particularly preferred that the invention be used to provide repeated or continuous monitoring of a property or properties throughout the production of the batch.

It will be seen that this preferred form of the invention is particularly useful because bulk properties can now be checked during production so there can be confidence that a batch of product is going to be on-specification.

A further significant benefit is provided in accordance with a preferred form of the invention in which the data produced in step (b) of the invention is used to assist in controlling the production plant. It will be appreciated that instead of simply bringing current production back into specification, using the invention in this manner allows a correction to be made to compensate for previously out of specification product.

Thus, a significant benefit is provided in that a product that would otherwise be out of specification (which would therefore have had to be either wasted or sold as a lower grade) can be remedied and brought back within the specification of the desired higher grade.

The invention may be used to assist in the manual control of the production plant. For example, a display may be provided in the control room indicating the current bulk property (e.g. bulk density of polymer contained in a silo), preferably together with the current sample density (i.e. the density of the current production) and the target bulk density. The plant controller can then take remedial action when necessary. Thus, if the bulk property has drifted away from specification, the current properties of the production may be varied (possibly putting them temporarily out of specification) in order to bring the bulk property closer to the desired bulk specification.

As an example, if the calculated overall density of the product were too low, for a limited period, product could be made at higher than specification density in order to bring the bulk density back to the desired value.

There may also, for example, be cases where the instantaneous property is too high (according to specifications), but the calculated batch property up to this specific time shows that it will be on the low side of the specification. Thus the correct intervention from the operator is to keep the property at its current (high) level (if the goal is to get as close as possible to the specification target).

It will be appreciated that in many circumstances there may be a limit to how far such corrections can be made without making the standard deviation of the property excessively large (which may itself put the product out of specification). This should be considered when determining how frequently the on-line measurements should be made. If the measurements are made on a frequent basis then the corrections involved should be comparatively small. In fact, a sample having an excessively large standard deviation would generally not be detected by the known (spot sampling) technique, whereas it may readily be detected by means of the present invention.

Thus, it will be appreciated that the repeated measurements should preferably be made sufficiently frequently to follow significant fluctuations in product quality. In most cases, this means that a measurement should be taken at least every 10 minutes and preferably more frequently than this, for example at least every 5 minutes. However, if a product quality is liable to fluctuate rapidly then intervals of less than two minutes, and possibly even as short as one minute, may be appropriate.

Although suitable time intervals may be determined empirically, it is preferred that the sampling frequency be calculated using the well-known Nyquist Sampling Theorum (see H. Nyquist, “Certain Factors Affecting Telegraph Speed”, The Bell System Technical Journal, Vol. 3, pp. 324-47, July 1924.) This may be stated as: “If the signal we are looking at changes at a maximum frequency of f, then we must sample at least 2*f to capture the detail”. Thus, preferably the sampling frequency is at least twice the frequency of anticipated significant changes in the product property being tested.

Although, as mentioned above, the data may be used manually by a plant controller, it is preferred that the correction process be automated. Thus, the method of the invention may be performed under computer control and be linked to an automatic process control system. To achieve this, the on-line measuring device may be arranged to provide an output signal that is fed, via an analogue to digital converter to an input port on the computer. At predetermined times, under software control, the input may be read and its value used to determine a value corresponding to the bulk property by means of a suitable software routine. This value may then be used to provide an output signal that may in turn be fed to an automatic process controller.

Thus, viewed from another aspect, the invention provides a method of controlling a production process in which data directly related the aggregate properties of the batch of product produced so far are used to control the process in order to maintain the aggregate properties within specification.

As previously noted, the invention is widely applicable. Although the present specification discusses the invention in detail in relation to polymer production, there are numerous other fields of application, particularly in relation to gaseous, liquid, powder and pellet (or other particle) production.

By way of example, the invention may be applied in the production of oxygen for clinical use, which has very strict limits on purity. By measuring the purity with an online instrument, it is possible to calculate the purity of a batch (stored in a pressurised vessel, possibly liquefied). The purpose of the online measurement is thus twofold: to monitor the production process, and to calculate the purity of the batch. The fluid (oxygen and impurities) will be homogenous throughout the tank after some time (whether it is liquefied or not), and any fraction bottled from the tank will have the purity calculated by the method described.

As a further example, the invention may also be applied in a similar (although less critical) manner in the production of soft drinks. These are commonly produced in batches and it is desirable for each batch to be produced to a similar specification. Thus, online measurement of the product e.g. as it is fed to a storage vessel may be used to calculate the properties of the bulk product within that vessel.

Any sort of online measurement that produces data that gives information relating to any useful batch property may be used in the invention.

For example, particularly in the field of polymer production, a spectrometer, such as an acoustic spectrometer or a spectrophotometer may be employed. For example, an NIR (near infra-red) spectrophotometer may be used to measure the spectrum of polymer fluff passing through a conduit from the production plant. As is well known in this art, such apparatus may be used to provide information from which product density may be derived. The set of repeated samples of this data may then be used to derive the density of the batch of polymer produced so far.

Another option is to use rheometric measurements. For example, a rheometer may be associated with an extruder which is used to homogenise and pelletise the polymer fluff. In such an apparatus, viscosity measurements are made at various pressures and these may in turn be used to determine the melt flow rate which is related to the molecular weight of the polymer. They corresponding bulk property can then be calculated.

Where the property concerned is additive, samples are taken at regular intervals and the production rate is substantially constant, it may only be necessary to determine the mean of the values of the property determined in step (a) from the start of the batch onwards. However, certain properties, such as density, are not additive. (The overall density of a set of particles mixed together is not equal to the mean of the individual densities of the particles.) In such cases more complex calculations are required—in the case of density the bulk (reciprocal of density) may be found, then averaged and converted into a density value.

However, it is common for production rate to vary significantly, especially at the beginning or end of a production campaign. Moreover, certain variations in product property are related to changes in production rate. Preferably, therefore, the calculation of a batch property takes into account the production rate at the times the relevant measurements occur. In this way the values corresponding to high production rate can be weighted accordingly.

This may be achieved by measuring the flow rate of the product passing through the online measuring apparatus if all the product passes via that apparatus, or by measuring the flow rate separately if the online measurement is taken on a bypass from the main conduit. In this way, it may be determined what quantity of product is produced with the particular measured value. The flow rate may be measured using any suitable known apparatus, such as a weight loss feeder.

However, as an alternative to directly measuring the flow rate of product, it may be calculated, for example on the basis of mass balance considerations.

Once the measured values of product properties and the corresponding production rates are known, the bulk property may be determined in various ways. Preferably, the batch properties are calculated continuously through the production time of a batch, and integrated with respect to the production rate.

As has already been discussed, a simple case is when the product property is additive. The integrated property is then given by:—

$${p}_{final} = \frac{{\int }_{o}^{T} ( {p}_{( t )} \cdot {\dot{m}}_{( t )} ) ⅆ t}{{\int }_{0}^{T} \dot{{m}_{( t )}} ⅆ t }$$

Where p₍ₜ₎ is the measured property value at time t, \dot{m}₍ₜ₎ is the measured production rate at time t(volume or mass flowing through a given point per unit time), and T is the total production time for the batch. If the property is non-additive, an integral describing the mixing must be used. The discrete form of the integral is then found. For the above additive property integral, the discrete form may be determined using the trapezoid integral method.

In addition to this, the standard deviation (and/or other parameters related to statistical process control (SPC)) for all calculated property values throughout the production time of the batch may be calculated. This may be compared to the expected standard deviation for the online measurement method (the measurement noise). If the calculated standard deviation for the process is higher than the expected standard deviation for the measurement method, there may be property inconsistencies in the batch. A final check could also be to plot the distribution of all property measurements, to detect bi- or multi-modal distributions of a property.

As a more concrete example, consider the measured property p₍ₜ₎ and the corresponding production rate \dot{m}₍ₜ₎ at times t during the production of a batch:

$$\begin{matrix}t & 0 & 1 & 2 & 3 \\ {p}_{( t )} & 3 & 4 & 4 & 1 \\ {\dot{m}}_{( t )} & 3 & 1 & 2 & 6\end{matrix}$$

Disregarding the variation in the production rate indicated by the different values of \dot{m}₍ₜ₎, the property mean for the batch is:—

$$\overline{p} = {\sum }_{i = 1}^{4} \frac{{p}_{( i )}}{n} = \frac{3 + 4 + 4 + 1}{4} = {3}_{=}$$

However, using the trapezoid numerical integration method which does account for the changes in production rate gives:—

$${p}_{final} = \frac{{\int }_{0}^{T} ( {p}_{( t )} \cdot {\dot{m}}_{( t )} ) ⅆ t}{{\int }_{0}^{T} {\dot{m}}_{( t )} ⅆ t} = 2.6$$

As a further example, density, which is not an additive property, is considered. Because it is non-additive, a special integral has to be developed. For polyolefins, specific volume (1/ρ) is sufficiently additive to give accurate results. The integral is then:—

$${p}_{final} = \frac{{\int }_{0}^{T} {\dot{m}}_{( t )} ⅆ t}{{\int }_{0}^{T} ( \frac{1}{{p}_{( t )}} {\dot{m}}_{( t )} ) ⅆ t} ,$$

Where \dot{m}₍ₜ₎ is mass flow rate. The expression in the denominator is then the volumetric rate. This integral may then be used as previously described.

The invention also extends to an apparatus which may be used to perform the method of the invention and so viewed from a further aspect the invention provides an apparatus for monitoring a bulk property of a product during its production comprising an input for receiving data corresponding to repeated on-line measurements of samples of the product which provide data related to a product property, the apparatus being arranged to use this data to determine a bulk property of the product so far produced.

Preferably the apparatus is also arranged to receive production rate data as previously discussed and to use such data in determining the bulk property.

Although such apparatus may be supplied separately from the source(s) of the input data, in use the apparatus further comprises one or more measuring devices such as those already described which supply the input data.

The determination of the bulk property is preferably carried out by means of a computer under software control. It may use an algorithm based upon the principles described above. The software may also be used to determine when input data is to be read.

An example of such an algorithm written in pseudo-programming language follows. It is suitable for use with an additive property, and finds both the accumulated mean of the property and the corresponding standard deviation:—

for each new property measurement p and corresponding
instantaneous production rate m, do:

if first sample then

−> Standard deviation std is zero when we
−> only have one sample
std = 0
−> Accumulated production n
n = m
−> Property mean pm
pm = p
−> Sum of squares ss
ss = m*p*p

else

−> Find the accumulated production n
n = n_{(old)} + m
−> Update estimates on property mean pm
pm = ((n−m)*pm_{(old)} + m*p) / n
−> Update estimates on sum of squares ss
−> and standard deviation std:
ss = ss_{(old)} + m*p*p
std = sqrt((ss − n*pm*pm) / (n − 1))

end if

end for

The sampling interval is constant. Production rate m is the instantaneous production rate at the time of the data aquistion. It is assumed that the production rate during each cycle is constant. This is a valid assumption when the time interval between each sample is short.

It will be seen that accumulated production n is updated each sampling interval by adding to it the instantaneous production rate m. (As the sampling interval is constant it is not necessary to convert rate m into standard units). In addition, property mean pm is repeatedly updated to provide a mean value of property measurement p for the accumulated production. The new value of pm is found by multiplying the old value of pm by the old value of n (=n−m), adding this to the current value of p multiplied by the current production rate m and dividing the answer by the new accumulated production n. Thus, it provides a suitably weighted mean of pm (accumulated mean value of p. Likewise, an updated value of the standard deviation (std) is found. As may be seen, this uses an updated accumulated sum of the current product property measurement p squared and multiplied by m. From this is subtracted the updated product mean pm squared multiplied by n (n being the sum of all m). The result of this is divided by (n−1) and the square root found to give the standard deviation.

It will be seen that the algorithm works on the basis of continually updating the values of mean and standard deviation, rather than calculating them afresh each cycle. This is highly advantageous. As an example, the additive property p was measured to be 2 at t1 and 3 at t2. The mass flow rate m was 7 kg/s at t₁ and 6 kg/s at t₂, and the time distance between t₁ and t₂ was 1 sec. Thus we have 7 mass units with property p=2 between t₀ and t₁, and 6 mass units with property p=3 between t₁ and t₂. The property mean is:

$$\overline{p} = \frac{7 \cdot 2 + 6 \cdot 3}{7 + 6} = 2 , 46$$

The standard deviation is:

$$std = \sqrt{\frac{7 \cdot {( 2 - 2 , 46 )}^{2} + 6 \cdot {( 3 - 2 , 46 )}^{2}}{7 + 6 - 1} = 0 , 52}$$

This way of calculation the mean and standard deviation is cumbersome as one has to store all p and m data for each new t until a batch is completed, and do a complete recalculation at each step. With the updating method used in the above algorithm, this is not necessary. The updating method is also very simple to implement in any computer system.

A further consideration is that, if there is a very large number of measurements, the sum of squares in the updating method will eventually become too large to process. If necessary, this problem may be overcome using the mean sum of squares in the algorithm.

An alternative algorithm that uses trapezoid integration and which may be adapted for use with non-additive properties follows:—

for each new property measurement p and corresponding
instantaneous production rate m, do:

if first sample then

−> Standard deviation std is zero when we
−> only have one sample
std = 0
−> set initial values for t_{old} n and m_{old}
t_{old} = 0
n = 0
m_{old} = initial production rate (at t = 0)
−> Find the accumulated production n
−> (trapezoid integration):
n = n + (t − t_{(old)})*(m + m_{(old)})/2
−> Property mean pm (and helper variable pmprod)
pm = p
pmprod = p*m
−> Sum of squares ss
ss = m*p*p

else

−> Find the accumulated production n
−> (trapezoid integration):
n = n + (t −t_{(old)})*(m + m_{(old)})/2
−> Update estimates on helper variable pmprod
−> and property mean pm (trapezoid integration):
pmprod = pmprod_{(old)} +

(t − t_{(old)})*(p*m + p_{(old)}*m_{(old)})/2

pm = pmprod / n
−> Update estimates on sum of squares ss
−> and standard deviation std:
ss = ss(old) +

(t − t(old))*(m*p*p + m(old)*p(old)*p(old))/2

std = sqrt((ss − n*pm*pm) / (n − 1))

end if

end for

It will be seen that this algorithm follows the same basic structure as the one described earlier, but that since it uses trapezoid integration the time interval between each cycle may vary.

There may also be provided suitable display equipment and/or output devices to enable data to be transmitted to process control systems.

More generally, the apparatus is preferably configured to operate in accordance with some or all of the preferred aspects of the method of the invention previously described.

The invention further extends to a production facility for producing product in batches, such as a polymer production plant, that either uses the method of the invention or incorporates the apparatus of the invention. It also extends to product made by means of the invention.

Certain embodiments of the invention will now be described, by way of example only, with reference to the accompanying drawings:—

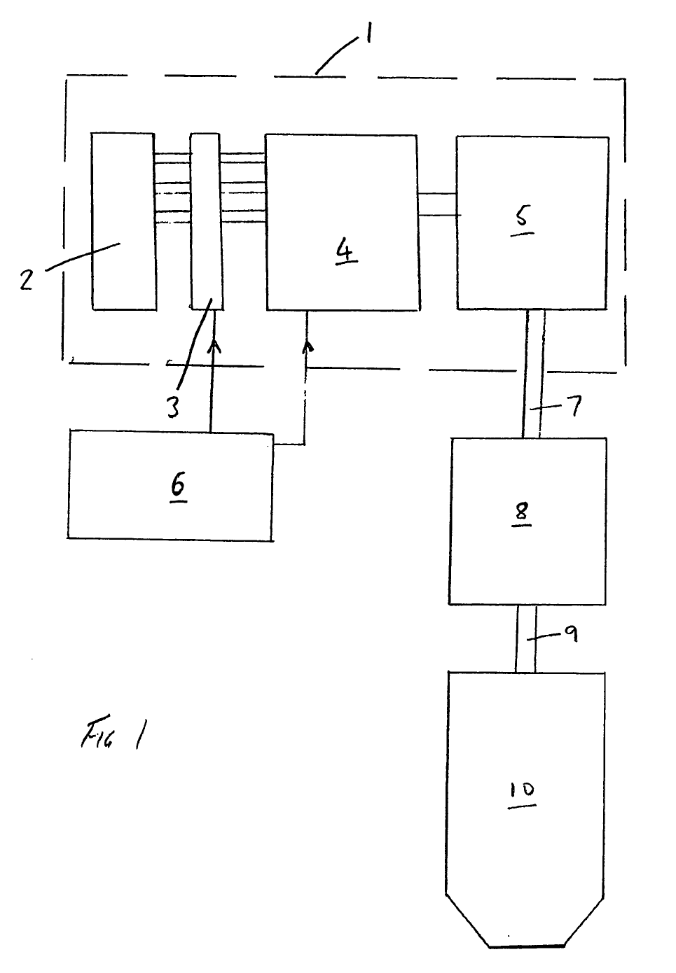

FIG. 1 is a schematic diagram illustrating a typical polymer production plant in which the present invention may be incorporated;

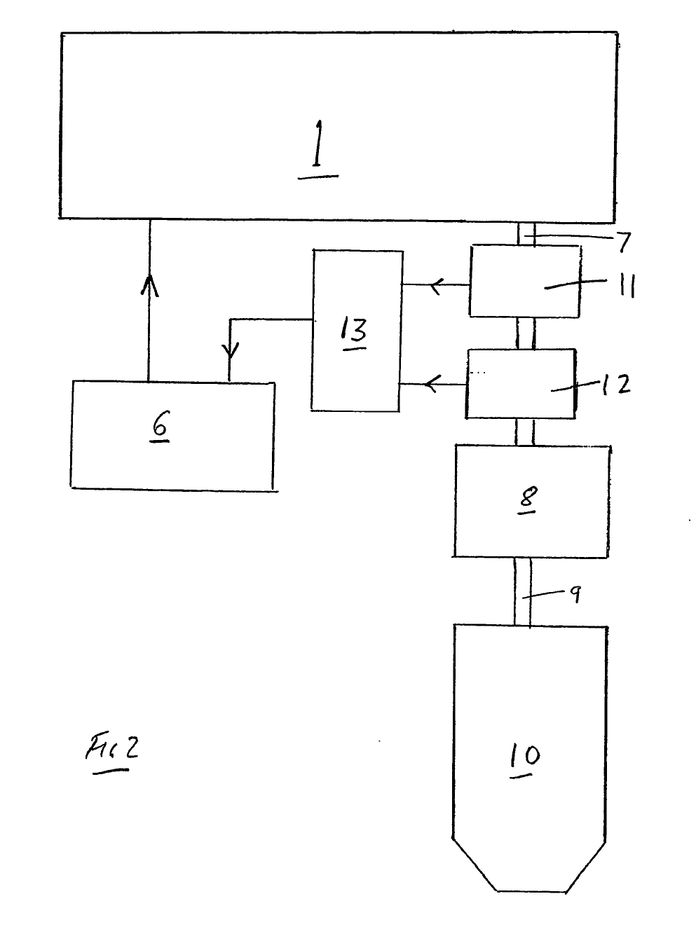

FIG. 2 of is a schematic diagram illustrating a polymer production plant incorporating a first embodiment of the invention; and

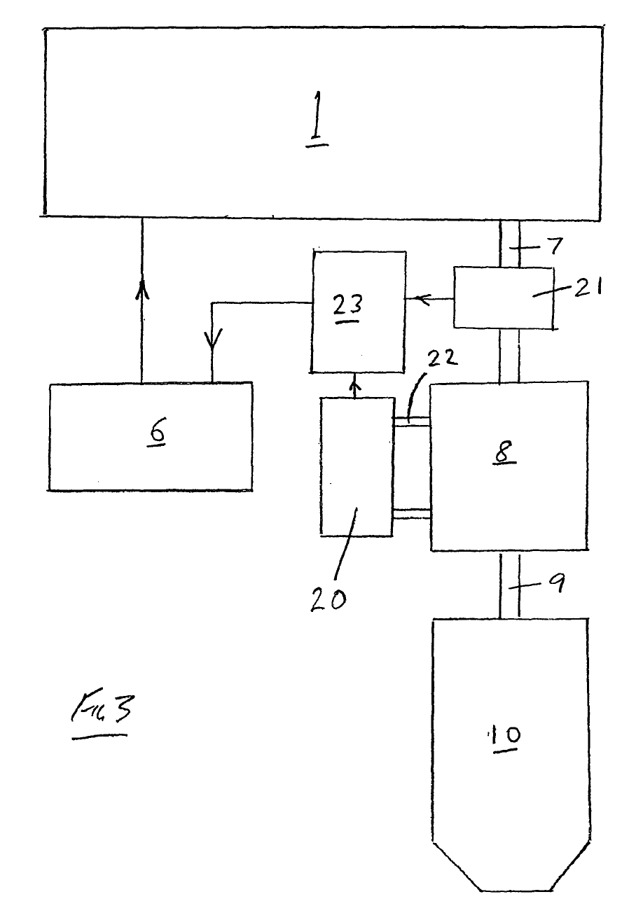

FIG. 3 corresponds to FIG. 2 but is modified in order to incorporate a second embodiment of the invention.

FIG. 1 illustrates, in a highly schematic form, a typical polymer production plant. The main plant apparatus 1 comprises a source of reactants, catalysts etc 2 which are connected via and number of control valves (illustrated and collectively at 3) to loop reactor 4.

Slurry containing a high concentration of polymer fluff leaves reactor 4 via a settling leg (not shown) from which it is fed to a flash drum 5. In the flash drum 5, the polymer fluff is separated from the other components which may be partly recycled.

Polymer from the flash drum is then carried pneumatically along conduit 7 to extruder 8 where it is melted, homogenized and turned into pellets.

The pellets are then transported via conduit 9 to silo 10. The silo 10 typically has a capacity of around 150 metric tonnes which comprises a single batch of production.

The production plant 1 is controlled by a computerized automatic control system 6 which uses various input measurements (not shown) on the basis of which it controls the flow of reactants into the reactor by a controlling valves 3. It also controls the reactor conditions, etc.

It should be understood that such reactors are extremely well known and so a highly simplified description is given here is merely to place the subsequent embodiments in context.

The first embodiment of the invention is illustrated in FIG. 2. It will be seen that production plant 1, extruder 8, silo 10 and process controller 6 are as shown in FIG. 1. To these components has been added a weight loss feeder 11 which measures mass flow rate, an NIR spectrometer 12 and data processor 13.

The basic principle of operation of the production plant is as described in relation to FIG. 1. As polymer produced by the plant 1 passes along conduit 7 the weight loss feeder 11 measures its mass flow rate. It is then passed through spectrometer 12 which produces a near infra-red spectrum of the polymer. The mass flow rate and the spectral data are transmitted to data processor 13 where they are used to calculate firstly the instantaneous polymer density and then the bulk density of the polymer in the silo. This is done using an algorithm based on the previously described equation for bulk density. The output from a data processor 13 is fed to process controller 6 which, if necessary, makes suitable adjustments to process conditions in order to maintain the desired bulk density value for the product in the silo 10. Alternatively, or additionally the data is presented in the plant control room on a display. The integrated density is displayed to the operator as an absolute number, and as a graph. The number is useful to the operator in the sense that the operator knows (at any time) what the final property value for the complete batch is.

FIG. 3 illustrates a second embodiment of the invention. Again, the basic components of the plants are unchanged. However, a mass-flow measuring device 21 corresponding to device 11 in FIG. 2 is provided, together with a rheometer 20 and a data processor 23.

A small proportion of polymer flowing through the extruder is diverted through a bypass 22 which leads to a rheometer 20. This produces data concerning the melt flow rate of the polymer in the known manner. This data is then transmitted, along with the mass flow data from device 21 to data processor 23. The data processor 23 calculates the corresponding properties of the bulk material in the silo in a manner directly analogous to that described in respect of the first embodiment.

1. A method of monitoring a bulk property of a product during its production comprising the steps of:
a) making repeated on-line measurements of samples of the product to obtain data related to a product property; and
b) using this data, determining a bulk property of the product so far produced.

2. A method as claimed in claim 1 wherein repeated or continuous determination of the bulk property is made throughout the production of the batch.

3. A method as claimed in claim 2, wherein the bulk property thereby determined is used to assist in controlling the production plant.

4. A method as claimed in claim 1, wherein the measurements of step (a) are made sufficiently frequently to follow significant fluctuations in product quality.

5. A method as claimed in claim 4, wherein the sampling frequency is at least twice the frequency of anticipated significant changes in the product property being tested.

6. A method as claimed in claim 4, wherein a measurement is taken at least every 10 minutes.

7. A method as claimed in claim 6 wherein a measurement is taken at least every 5 minutes.

8. A method as claimed in claim 1, wherein the calculation of a batch property takes into account the production rate at the times the relevant measurements occur.

9. A method of controlling a polymer production process in which data directly related the aggregate properties of the batch of product produced so far are used to control the process in order to maintain the aggregate properties within specification.

10. An apparatus for monitoring a bulk property of a product during its production comprising an input for receiving data corresponding to repeated on-line measurements of samples of the product which provide data related to a product property, the apparatus being arranged to use this data to determine a bulk property of the product so far produced.

11. An apparatus as claimed in claim 10 arranged additionally to receive data indicative of production rate and to use such data in determining the bulk property.

12. An apparatus as claimed in claim 10, further comprising one or more measuring devices arranged to supply the input data.

13. An apparatus as claimed in claim 12 wherein an NIR spectrometer is used to provide input data.

14. An apparatus as claimed in claim 12, further comprising a weight loss feeder arranged to provide input data indicative of current production rate.

15. An apparatus as claimed in claim 10, wherein determination of the bulk property is carried out by means of a computer under software control.

16. A polymer production plant comprising an apparatus for monitoring a bulk property of a product during its production comprising an input for receiving data corresponding to repeated on-line measurements of samples of the product which provide data related to a product property, the apparatus being arranged to use this data to determine a bulk property of the product so far produced.
